(19) United States
(12) Patent Application Publication
(10) Pub. No.: US 2010/0117188 A1
(43) Pub. Date: May 13, 2010

(54) METHOD FOR PRODUCING TRENCH ISOLATION IN SILICON CARBIDE AND GALLIUM NITRIDE AND ARTICLES MADE THEREBY

(75) Inventors: Peter Wilson Waldrab, Schenectady, NY (US); James William Kretchmer, Ballston Spa, NY (US); Jason David Galea, Watervliet, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/682,067

(22) Filed: Mar. 5, 2007

(51) Int. Cl. H01L 29/06; H01L 21/762; H01L 21/306

(52) U.S. Cl. 257/506; 438/424; 438/430; 156/345.1; 257/E21.546; 257/E29.02

(57) ABSTRACT

A method for fabricating a trench in a SiC or GaN semiconductor wafer is provided. The method may include filling the trench with a conformal layer of electrically and/or optically isolating material. A device is also provided.

### GOVERNMENT RIGHTS

This invention was made with Government support under contract number FA8650-05-C-7201 awarded by the United States Air Force (USAF). The Government may have certain rights in the invention.

### BACKGROUND

1. Technical Field

Some embodiments may relate to integrated circuit and/or optical array components. Some embodiments may include isolation trench components.

2. Discussion of Related Art

Integrated circuits and optical arrays may include components located in close proximity to each other. Such components may interfere with each other if they are not sufficiently isolated. Therefore, isolation components may be fabricated to provide electrical and/or optical isolation. Due to difficulties in etching silicon carbide (SiC) and gallium nitride (GaN), devices comprising such materials are limited in the types of isolation components with which they are compatible. Previously, isolation components that could be fabricated on SiC and GaN substrates included heavily doped isolation regions, LOCOS, and wide mesa structures. Some existing isolation components and methods are not suitable for providing optical isolation. Furthermore, some are time consuming, expensive, and/or incompatible with SiC and/or GaN. Still further, some occupy a relatively large amount of space.

It may be desirable to have an isolation component that differs from those designs that are currently available. It may be desirable to have a method of making an isolation component that differs from those methods currently available.

### BRIEF DESCRIPTION

An embodiment according to the invention includes a method. The method may include forming at least one trench through an exposed surface of a semiconductor wafer. Removing a portion of the semiconductor wafer material may form the trench. The semiconductor may comprise a material selected from the group consisting of silicon carbide and gallium nitride. The method may also include forming an electrically or optically isolating layer on the sidewalls and the bottom of the at least one trench. The electrically or optically isolating layer may fill the at least one trench. The method may further include planarizing the semiconductor wafer surface by removing the portion of the electrically or optically isolating material above the exposed surface of the semiconductor wafer.

An embodiment according to the invention may include a device. The device may include at least two integrated components. The at least two integrated components may be located in a substrate selected from the group consisting of silicon carbide, gallium nitride and a combination thereof. The device may further include at least one trench in the substrate. The at least one trench may be disposed between the at least two integrated components. The inside of the at least one trench may be filled with a conformally deposited material that is electrically isolating, optically isolating, or both electrically and optically isolating.

### BRIEF DESCRIPTION OF THE DRAWING FIGURES

FIG. 1 is a flowchart showing several steps of a process embodiment;

FIG. 2 is a electron micrograph showing an undercut structure having a Ti/Ni etch mask;

FIG. 3 is a pictorial flowchart showing a device at various stages of processing;

FIG. 4 is a pictorial flowchart showing a device at various stages of processing; and

FIG. 5 is a pictorial flowchart showing a device at various stages of processing.

### DETAILED DESCRIPTION

The invention may include embodiments that relate to one or more integrated circuit and/or optical array components. Some embodiments may relate to one or more methods associated with one or more integrated circuit and/or optical array component.

Approximating language, as used herein throughout the specification and claims, may be applied to modify any quantitative representation that could permissibly vary without resulting in a change in the basic function to which it is related. Accordingly, a value modified by a term such as “about” may not to be limited to the precise value specified, and may include values that differ from the specified value. In at least some instances, the approximating language may correspond to the precision of an instrument for measuring the value. Similarly, “free” may be used in combination with a term, and may include an insubstantial number, or trace amounts, while still being considered free of the modified term. The terms “top” and “bottom” have their ordinary meanings. “Conformal” means that a first surface is followed or mapped by a contacting second surface with such accuracy that shapes and irregularities in the first surface are precisely complemented by the second surface.

One embodiment may include an isolation trench. According to some embodiments the trench may include a substrate comprising SiC, GaN, or a combination thereof. Other suitable substrates may include GaN alloys. According to some embodiments, such a trench may have an open top side that breaks a top surface of the substrate, at least two approximately vertical sidewalls, and a bottom side. The bottom side may be approximately perpendicular to the sidewalls, and may be approximately parallel to the top side. In some embodiments, the isolation trench includes at least four approximately parallel sidewalls. In some embodiments, the sidewalls may have a cross section, taken parallel to the bottom side of the trench, that may be an appropriate shape including, but not limited to, a polygon, a rectangle, or a trapezoid. In some embodiments, the cross section may be approximately square. According to some embodiments, the isolation trench may be deeper than the junction depth of the device or devices that it isolates.

In some embodiments, an isolation trench may have a width from about 0.1 μm to about 4.0 μm. According to some embodiments an isolation trench may have a width from about 0.1 μm to about 0.5 μm, from about 0.5 μm to about 1.0 μm, from about 1.0 μm to about 1.5 μm, from about 1.5 μm to about 2.0 μm, from about 2.0 μm to about 2.5 μm, from about 2.5 μm to about 3.0 μm, from about 3.0 μm to about 3.5 μm, or even from about 3.5 μm to about 4.0 μm. Here, as elsewhere throughout the specification and claims, ranges may be combined. The trenches may be narrow enough to be filled. For example, a 4.0 micrometer wide trench may be filled by a conformal film of silicon oxide or polysilicon.

According to some embodiments, trenches within the scope of embodiments of the invention may have depths of several micrometers (μm), e.g. 5 μm, or more. Trench depths of up to 100 micrometers may be utilized in some cases. However, depths of less than 10 micrometers may be utilized. The trenches may have an aspect ratio (i.e., trench depth divided by width) from about 0.5 to about 1.0, from about 1.0 to about 1.5, from about 1.5 to about 2.0, from about 2.0 to about 2.5, from about 2.5 to about 3.0, from about 3.0 to about 3.5, from about 3.5 to about 4.0, from about 4.0 to about 4.5, from about 4.5 to about 5.0, from about 5.0 to about 5.5, from about 5.5 to about 6.0, from about 6.0 to about 6.5, or greater than about 6.5. The depths and other geometrical properties of the trenches can be determined so as to effectively provide optical and/or electrical isolation between adjacent devices.

According to some embodiments, photolithography and/or anisotropic etching may be used to fabricate trenches. A suitable etch mask may be selected according to the desired depth of the trenches. A soft mask may be used for fabricating relatively shallow trenches, e.g. less than about 5 μm. For example, a soft mask may include a photoresist mask of a few micrometers. A hard mask, such as a nickel or aluminum metal, may be used for fabricating trenches deeper than about 5 μm. In the case of a metal etch mask, image-reversal a photolithographic process may be combined with a metal lift-off process to fabricate a trench opening pattern on a semiconductor wafer surface. Openings in the mask layer may expose the underlying wafer surface in predetermined locations for etching trenches. Then the wafer may be subjected to an anisotropic etching process, such as reactive ion etching (RIE) or an inductively coupled plasma (ICP) process, for example. After etching, additional process steps may be carried out to remove the etch mask, and/or any etching by-product, from the wafer surface and the trenches. Other lithographic and/or etching techniques may be used, alone or in combination, to fabricate deep trenches.

Some embodiments may include at least one electrically and/or optically isolating layer. The layer may be disposed on the sidewalls and on the bottom side of the trench. Furthermore, in some embodiments, the layer material approximately fills the trench. Suitable isolating layers may conform to the topology of the trench during growth. Thus, in some embodiments, the isolating layer may grow conformally from or on the sidewalls and bottom of the trench. In some embodiments the conformal layer is sufficiently regular to prevent or diminish the formation of voids under a surface of the layer.

According to some embodiments, suitable materials for forming an electrically isolating conformal layer can include, without limitation, silicon oxide (SiO₂) hafnium oxide (HfO₂), scandium oxide (ScO₂), silicon nitride (Si₃N₄), or a combination of two or more thereof. According to other embodiments, suitable materials for forming an optically isolating conformal layer can include polycrystalline silicon (Si), titanium (Ti), aluminum (Al), tungsten (W), or a combination of two or more thereof. Furthermore, the conformal isolating layer can comprise a combination of the foregoing optically and electrically isolating materials. The conformal layer may comprise other electrically and/or optically isolating materials or combinations of materials. In one embodiment, the conformal layer consists essentially of an electrically isolating material or combination of materials. In one embodiment, the conformal layer consists essentially of an optically isolating material or combination of materials.

In some embodiments the electrically and/or optically isolating layer may be grown on the semiconductor wafer surface by thermal oxidation, chemical vapor deposition, low-pressure chemical vapor deposition, epitaxial growth, or a combination thereof. According to some embodiments, the isolating layer may be conformally deposited at temperatures less than about 1000 degrees Celsius. In one embodiment, a conformal LPCVD dichlorosilane-based HTO is deposited at about 900 degrees Celsius. Alternative suitable deposition techniques include PECVD and PVD.

According to some embodiments the optically isolating layer may be opaque to a selected radiation band. For example, radiation bands may include wavelengths from about 100 nanometers (nm) to about 150 nm, from about 150 nm to about 200 nm, from about 200 nm to about 250 nm, from about 250 nm to about 300 nm, from about 300 nm to about 350 nm, from about 350 nm to about 400 nm, from about 400 nm to about 450 nm, from about 450 nm to about 500 nm, from about 500 nm to about 550 nm, from about 550 nm to about 600 nm, from about 600 nm to about 650 nm, from about 650 nm to about 700 nm, from about 700 nm to about 750 nm, from about 750 nm to about 800 nm, or greater than about 800 nanometers.

According to some embodiments a top surface of the semiconductor wafer may be planarized. A planarizing step may produce a flat surface on a face of the wafer. Furthermore, the surface may be sufficiently flat to lessen or preclude problems related to surface roughness or topology. A planarizing step may comprise removing a portion of isolating material above a top surface of the semiconductor wafer. According to some embodiments, planarizing may include oxidizing a portion of the isolating material, and then removing the resulting oxide by wet chemical etching. For example, when polycrystalline silicon is used to fill a trench fabricated in a SiC wafer, the oxidation rate of polycrystalline silicon is much greater than that of SiC. Thus, the wafer may be planarized while consuming very little of the SiC semiconductor substrate. According to another embodiment, the isolating material is selectively etched away with a plasma etcher. In yet another embodiment, planarizing can include subjecting the wafer to a chemical mechanical polishing (CMP) process. These and other methods may be used alone or in combination.

According to some embodiments an isolation trench in accordance with the present invention may comprise an integrated circuit component. According to some embodiments, such an isolation trench may comprise one or more of a blue light emitting diode (LED), a Schottky diode, a metal-semiconductor field-effect transistor (MESFET), a high temperature insulated gate bipolar transistor (IGBT), an ultraviolet radiation detector, MOSFET, high electron mobility transistor, BJT, an optical sensor, or a thyristor. Some embodiments may be operable at high temperatures, which are inaccessible to integrated circuits that do not comprise SiC and/or GaN. Suitable integrated circuits may be useful at temperatures greater than about 100 degrees Celsius. Some embodiments may include integrated circuits that are operable in a temperature range of from about 100 Celsius to about 200 Celsius, from about 200 Celsius to about 300 Celsius, from about 300 Celsius to about 400 Celsius, or from about 400 Celsius to about 500 Celsius. Some embodiments may comprise integrated circuits that resist damage from radiation. Such radiation may include alpha particle, beta particle, gamma, or cosmic radiation. Furthermore, some embodiments may include integrated circuits that operate under radiation conditions under which other integrated circuits that do not include embodiments of the invention can not operate.

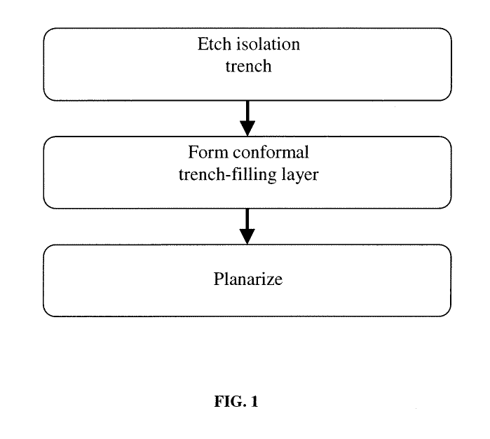

In one embodiment, an isolation trench is fabricated on a substrate according to the following steps. With reference to the flowchart in FIG. 1, a trench pattern is etched in a substrate. Then a conformal trench-filling layer is deposited on the substrate. The wafer is then planarized according to an appropriate method. The step of planarizing may remove isolation material from a top surface of the substrate, while leaving the trench structures filled with isolation material.

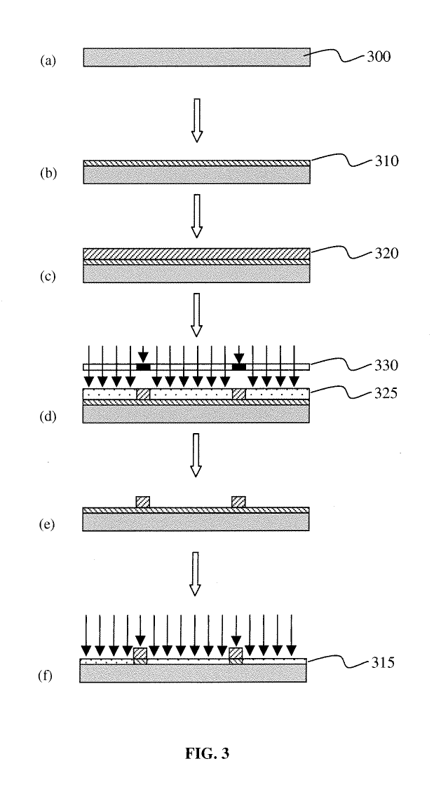

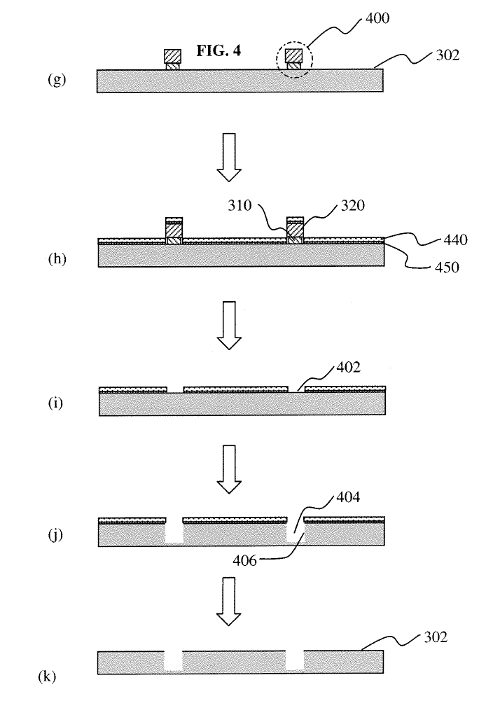

One embodiment, comprising a process for forming isolation trenches, is set forth here with reference to FIGS. 3, 4, and 5. A substrate 300 is provided (FIG. 3(a)), and spin coated with a liftoff photoresist 310 (FIG. 3(b)). The liftoff photoresist 310 may be an appropriately selected commercially available photoresist material. The liftoff photoresist 310 is cured and then spin coated with an appropriate masking photoresist 320 (FIG. 3(c)). The masking photoresist 320 is cured and then exposed through a photomask 330 to an amount and kind of radiation sufficient to photodegrade the masking photoresist 320 according to a predetermined pattern (FIG. 3(d)) without photodegrading the liftoff photoresist 310. The photodegraded masking photoresist 325 is then developed away (FIG. 3(e)), thereby leaving portions of the liftoff photoresist 310 unmasked. Then the liftoff photoresist 310 is exposed to an appropriate amount and kind of radiation sufficient to photodegrade unmasked portions of the liftoff layer 315 (FIG. 3(g)) without further photodegrading the masking photoresist 320. The masking photoresist 320 thus acts to pattern the exposure of the underlying liftoff resist 315. The photodegraded portions of the liftoff layer 315 are then developed away (FIG. 4(g)). According to some embodiments, the step of developing the exposed portion of the liftoff layer 315 may also remove a portion of the unexposed liftoff layer 310. Furthermore, according to some embodiments, the step may tend preferentially remove a portion of the unexposed liftoff layer 310 as compared to the remaining masking layer 320. Therefore, the step may yield a comparatively wide masking layer 320 overlaying a comparatively narrow liftoff layer 310, thus creating an undercut structure 400. The degree of undercut is tunable.

Alternatively, the above technique can be used in a less tunable, lower resolution capacity by eliminating the second exposure and/or second develop step if the initial develop is sufficient (given enough time) to cause undercut in the liftoff resist.)

Next, a layer of a first metal 450, such as titanium, is deposited unselectively on the surface of the wafer 302, and is then topped with a second metal 440, such as nickel (FIG. 4(h)). The kinds of metals and thicknesses of the layers may be selected so that the layers are effective to protect the underlying material from one or more reactive ion etching steps. The liftoff 310 and masking 320 layers are then removed according to appropriate methods, thus exposing the substrate 402 according to a predetermined pattern (FIG. 4(i)). The exposed substrate 402 is then anisotropically etched, for example, by a reactive ion etching process. The etching process is functional to produce a trench 404 having approximately vertical side walls 406 and a predetermined depth and width (FIG. 4(j)). The sidewalls may have a slight taper to allow conformal refill without voids. Then the metal layers 440, 450 are removed according to an appropriate process (FIG. 4(k)), thereby exposing the substrate 302.

For use with a silicon carbide substrate, a sacrificial oxidation step can be performed between the trench etching and the refill steps. The sacrificial oxidation can consume some of the substrate, thereby smoothing out roughness caused by the etch that can lead to microvoids in the refill. The sacrificial oxidation step can grow about 10 nanometers to about 100 nanometers of thermal oxide, which can then be removed with a solution of dilute hydrofluoric acid

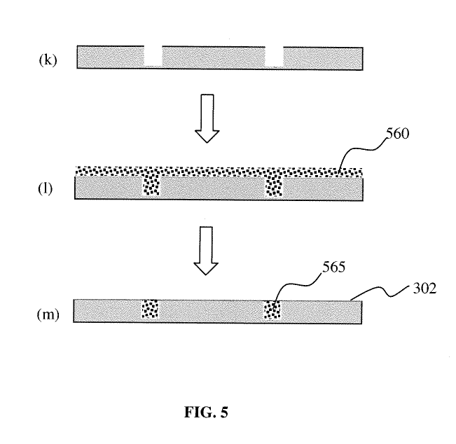

An isolating layer 560 may be conformally deposited or grown on the substrate to a predetermined thickness, by an appropriate means including chemical vapor deposition or thermal oxidation. The thickness may be sufficient to fill the trenches 404 (FIG. 5(l)). The conformal layer may be etched back to a substrate surface 302 to expose a portion of the substrate while leaving the trenches 404 filled with isolation material 565 (FIG. 5(m)). A material and design appropriate etching technique may be used for this step. Suitable etching techniques may include chemical etching, reactive ion etching, or chemical mechanical polishing methods.

### Example 1

### Gallium Nitride Substrate

According to Example 1, an isolation trench fabrication embodiment comprises the following steps. A gallium nitride (GaN) substrate is provided. The substrate surface is spin coated with 3% polydimethylglutarimide (PMGI) and baked at 250 degrees Celsius for 5 minutes. The PMGI layer may be referred to herein as a liftoff layer. The PMGI layer is then spin coated with a layer of I-line masking photoresist known as AZ MIR 703, and baked at 100 degrees Celsius for 1 minute. AZ MIR 703 is a mixture of 1-Methoxy-2-propanol acetate 62% (CAS #108-65-6); Cresol-novolak <35% (CAS #117520-84-0); and Daizonaphthoquinonesulfonic Esthers 5% (CAS #5610-94-6) and can be commercially obtained from Clariant Corp. (Somerville, N.J.).

The AZ MIR 703 layer is then exposed to I-line UV radiation through a photomask, which results in the photodegradation of the exposed portions of the AZ 703 layer. The photodegraded portion of the AZ MIR 703 layer is then developed away using tetramethlyammonium hydroxide, leaving the unexposed portions in tact. The uncovered portions of the PMGI liftoff layer are then exposed to deep UV radiation, e.g. about 248 nm, through the masking photoresist, causing chain scission in the liftoff layer. The photodegraded portion of the liftoff layer is selectively developed away using tetraethylammonium hydroxide. The selective development tends to dissolve the PMGI layer, while tending to leave the AZ 703 layer comparatively in tact. Thus, the AZ 703 layer may be wider than the supporting PMGI layer. The degree of difference in width between the two layers is tunable.

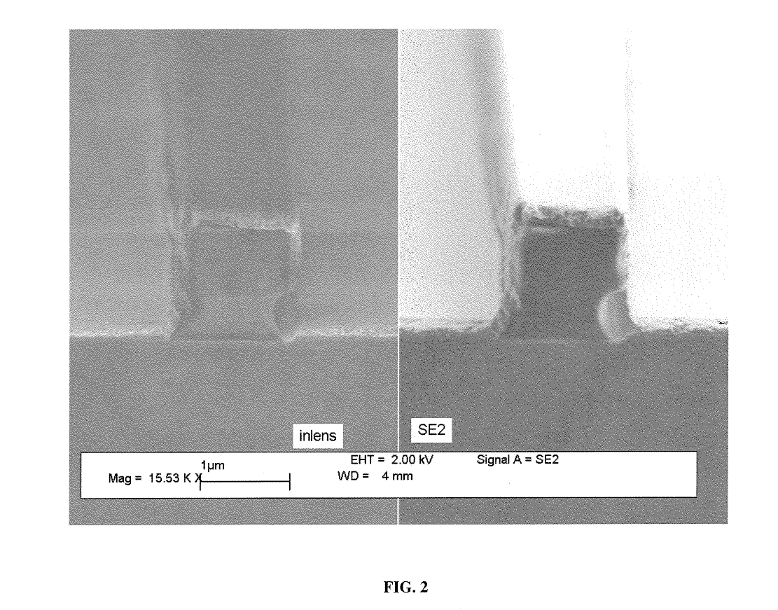

Next, a layer of titanium is deposited, for instance, according to an evaporation process. According to this example, the titanium layer has a thickness of about 50 nm. Then a layer of nickel is deposited on the titanium layer, for instance, according to an evaporation process. The thickness of the nickel may be about 200 nm (see FIG. 2). The substrate is then exposed according to a predetermined pattern by dissolving the PMGI liftoff layer in N-methylpyrrolidone at about 110 degrees Celsius. Optionally, dissolution may be promoted by applying ultrasonic waves, for example, at about 44 kHz. The exposed portions of the substrate are then anisotropically etched using an inductively coupled plasma reactive ion etch (ICP-RIE) tool. Then the nickel top layer is removed using a mixture of phosphoric and nitric acid heated to about 60 degrees Celsius. The underlying titanium layer is removed using dilute hydrofluoric acid solution.

According to Example 1, a conformal silicon oxide, or polycrystalline silicon, layer is deposited or grown on the substrate. Following this step, integrated components may be fabricated on the exposed substrate surface, and may benefit from optical and/or electrical isolation provided by the isolation trenches.

### Example 2

### Silicon Carbide Substrate

Example 2 is the same as Example 1, except that rather than gallium nitride as the substrate, silicon carbide (SiC) is used. In addition, after the deposit of the conformal silicon oxide layer on the substrate surface, the portion of the conformal layer above the top surface of the substrate is removed to expose the top surface of the substrate. The trenches remained filled with silicon oxide. In particular, a solution of dilute hydrofluoric acid, etches away the top layer while leaving the trenches filled with silicon oxide.

### Example 3

### Aluminum Gallium Nitride Substrate

Example 3 is the same as Examples 1 and, except that rather than gallium nitride or silicon carbide as the substrate, aluminum gallium nitride (AlGaN) is used. In addition, a reactive ion etching (RIE) method using fluoride ion, is used to remove the portion of the conformal layer above the top surface of the substrate rather than a dilute acid bath.

The embodiments described herein are examples of compositions, structures, systems and methods having elements corresponding to the elements of the invention recited in the claims. This written description enables one of ordinary skill in the art to make and use embodiments having alternative elements that likewise correspond to the elements of the invention recited in the claims. The scope thus includes compositions, structures, systems and methods that do not differ from the literal language of the claims, and further includes other compositions, structures, systems and methods with insubstantial differences from the literal language of the claims. While only certain features and embodiments have been illustrated and described herein, many modifications and changes may occur to one of ordinary skill in the relevant art. The appended claims are intended to cover all such modifications and changes.

What is claimed is:

1. A method, comprising:
forming at least one trench through an exposed surface of a semiconductor wafer by removing a portion of the semiconductor wafer material, wherein the semiconductor comprises a material selected from the group consisting of silicon carbide and gallium nitride;
forming an electrically or optically isolating layer on the sidewalls and the bottom of the at least one trench, wherein the electrically or optically isolating layer fills the at least one trench; and
planarizing the semiconductor wafer surface by removing the portion of the electrically or optically isolating material above the exposed surface of the semiconductor wafer.

2. The method according to claim 1, wherein forming the at least one trench comprises:
coating the semiconductor wafer with a liftoff photoresist layer formable material;
curing the liftoff photoresist layer formable material to form a liftoff photoresist layer;
coating the liftoff photoresist layer with a masking photoresist layer formable material;
curing the masking photoresist layer formable material to form a masking photoresist layer;
exposing through a photomask at least a exposed portion of the masking photoresist layer to electromagnetic radiation, wherein the amount and kind of radiation is sufficient to cause photodegradation of the masking photoresist in the exposed portion;
removing the photodegraded masking photoresist and unmasking at least a portion of the liftoff photoresist;
exposing at least a portion of the unmasked liftoff photoresist to an amount and to a kind of electromagnetic radiation sufficient to photodegrade an exposed portion of the liftoff layer;
removing the photodegraded portion of the liftoff layer and forming an undercut structure so that a portion of the unexposed liftoff layer is more narrow than the overlaying masking layer, wherein the degree of undercut is tunable;
depositing a first metal layer unselectively onto a top surface;
depositing a second metal layer unselectively onto an outward facing surface of the first metal layer;
removing the liftoff and masking layers to unmask a portion of the semiconductor wafer in a determined pattern;
etching the unmasked portion of the semiconductor wafer anisotropically to form a trench structure; and
removing the first and second metal layers.

3. The method according to claim 2, wherein the liftoff photoresist layer comprises polydimethylglutarimide, and the masking photoresist layer comprises a material derived from a novolak resin with absorption characteristics capable of masking actinic wavelengths of a photosensitive layer disposed therebelow.

4. The method according to claim 2, wherein the first metal layer comprises titanium and the second metal layer comprises nickel.

5. The method according to claim 2, wherein anisotropically etching comprises a reactive ion etching process using an ion selected from the group consisting of fluoride and chloride.

6. The method according to claim 2, wherein the anisotropically etching is functional to produce a trench structure having an aspect ratio from 0.5 to 6.5.

7. The method according to claim 1, wherein forming an electrically isolating layer comprises growing or depositing an oxide layer on the sidewalls and the bottom of the at least one trench.

8. The method according to claim 7, wherein the step of forming an electrically isolating layer comprises growing a silicon dioxide layer on the sidewalls and the bottom of the at least one trench.

9. The method according to claim 7, wherein the step of forming an electrically isolating layer comprises growing or depositing a layer comprising a composition selected from the group consisting of hafnium oxide, scandium oxide, silicon nitride or a combination thereof, on the sidewalls and the bottom of the at least one trench.

10. The method according to claim 7, wherein the optically isolating material comprises an opaque material capable of being deposited conformally.

11. The method of claim 10, wherein the optically isolating material can be deposited at a temperature below 900 degrees Celsius.

12. The method according to claim 1, wherein the optically isolating material comprises a composition selected from the group consisting of aluminum, silicon, titanium, tungsten, and a combination of two or more thereof.

13. The method according to claim 12, wherein the optically isolating material comprises polysilicon.

14. The method according to claim 1, wherein the at least one trench is located between a plurality of adjacent device sites.

15. The method according to claim 1, wherein the step of forming at least one trench comprises selectively etching the semiconductor wafer with reactive ion etching or an inductively coupled plasma process.

16. The method according to claim 1, wherein the step of planarizing the semiconductor wafer surface comprises:
oxidizing the portion of the optically isolating material above the exposed surface of the semiconductor wafer; and
removing the oxidized portion of the optically isolating material.

17. The method according to claim 16, wherein the step of planarizing the semiconductor wafer surface comprises subjecting the portion of the optically isolating material above the exposed surface of the semiconductor wafer to an etching process.

18. The method according to claim 16, wherein the step of planarizing the semiconductor wafer surface comprises subjecting the portion of the optically isolating material above the exposed surface of the semiconductor wafer to a chemical mechanical polishing process.

19. The method according to claim 1, wherein the step of planarizing the semiconductor wafer surface comprises etching the portion of the electrically isolating material above the exposed surface of the semiconductor wafer.

20. The method according to claim 17, wherein the step of etching comprises contacting the electrically isolating material with fluoride ion or a chloride ion.

21. A device comprising:
at least two integrated devices, wherein the at least two integrated devices are located in a substrate selected from the group consisting of silicon carbide, gallium nitride and a combination thereof; and
at least one trench in the substrate, wherein the at least one trench is disposed between the at least two integrated devices, and the inside of the at least one trench is filled with a conformally deposited material that is electrically isolating, optically isolating, or both electrically and optically isolating.

22. The microelectronic device according to claim 21, wherein the electrically isolating material is selected from the group consisting of silicon dioxide, silicon nitride, hafnium oxide, scandium oxide, and a combination thereof.

23. The device according to claim 22, wherein the electrically isolating material comprises a thermally grown silicon dioxide.

24. The device according to claim 21, wherein the optically isolating material is a low pressure vapor deposit of material selected from the group consisting of aluminum, silicon, titanium, tungsten or a combination of two or more thereof.

25. The device according to claim 24, wherein the optically isolating material comprises a low pressure chemical vapor deposition polysilicon.

26. The device according to claim 21, wherein the optically isolating material comprises an opaque material that can be deposited conformally under 900 degrees Celsius.

27. The device according to claim 21, wherein the device comprises a photodiode array, a blue light emitting diode, a Schottky diode, a metal-semiconductor field effect transistor, a metal oxide semiconductor field effect transistor, a high temperature insulated gate bipolar transistor, a thyristor, an ultraviolet light detector, a bipolar junction transistor, a high electron mobility transistor, or a combination of two or more thereof.

28. The device according to claim 21, wherein the device is capable of operating at a temperature in a range of from about 100 degrees Celsius to about 500 degrees Celsius.

29. The device according to claim 21, wherein the device is capable of resisting damage from radiation selected from the group consisting of alpha particle, beta particle, gamma, and cosmic radiation.

30. A semiconductor device fabrication system, comprising:
means for forming at least one trench through an exposed surface of a semiconductor wafer by removing a portion of the semiconductor wafer material, wherein the semiconductor comprises a material selected from the group consisting of silicon carbide and gallium nitride;
means for forming an electrically or optically isolating layer on the sidewalls and the bottom of the at least one trench, wherein the electrically or optically isolating layer fills the at least one trench; and
means for planarizing the semiconductor wafer surface by removing the portion of the electrically or optically isolating material above the exposed surface of the semiconductor wafer.
